(19) United States
(12) Patent Application Publication
(10) Pub. No.: US 2026/0172059 A1
(43) Pub. Date: Jun. 18, 2026

(54) HIGH FREQUENCY MODULE AND COMMUNICATION DEVICE

(71) Applicant: Murata Manufacturing Co., Ltd., Nagaokakyo-shi (JP)

(72) Inventors: Kazuhiro TAKAHASHI, Nagaokakyo-shi (JP); Tsubasa UCHIDA, Nagaokakyo-shi (JP)

(73) Assignee: Murata Manufacturing Co., Ltd., Nagaokakyo-shi (JP)

(21) Appl. No.: 19/394,915

(22) Filed: Nov. 20, 2025

(30) Foreign Application Priority Data
Dec. 13, 2024 (JP) 2024-219446

(51) Int. Cl. H04B 1/00; H03H 9/64; H04B 1/40

(52) U.S. Cl. CPC H04B 1/0057; H03H 9/64; H04B 1/40

(57) ABSTRACT

A high frequency module includes a mounting board, a first acoustic wave filter, an external connection terminal, a bonding conductor, and a through-conductor. The first acoustic wave filter is disposed over a first major surface of the mounting board. The bonding conductor is between the first major surface of the mounting board and the first acoustic wave filter. The through-conductor penetrates the mounting board, and is connected to the external connection terminal and the bonding conductor. The first acoustic wave filter has a first substrate and a first functional electrode disposed on a third major surface of the first substrate. A fourth major surface of the first substrate is connected to the bonding conductor. The bonding conductor and the through-conductor overlap the first functional electrode of the first acoustic wave filter in plan view from a thickness direction of the mounting board.

### CROSS-REFERENCE TO RELATED APPLICATION

The present application claims priority to Japanese patent application JP 2024-219446, filed Dec. 13, 2024, the entire contents of which are being incorporated herein by reference.

### BACKGROUND

### 1. Field

The present disclosure generally relates to a high frequency module and a communication device, and specifically relates to a high frequency module including an acoustic wave filter and a communication device including the high frequency module.

### 2. Description of the Related Art

A high frequency module including an acoustic wave filter is described in International Publication No. 2021/215107 (hereinafter, Patent Document 1). The high frequency module described in Patent Document 1 includes an acoustic wave filter over a mounting board, and the top surface of the acoustic wave filter is connected to a shield layer for improvement in heat dissipation properties. In a substrate of the acoustic wave filter, a major surface opposite to a major surface provided with a functional electrode is the top surface of the acoustic wave filter.

### SUMMARY

However, in the high frequency module of the related art described in Patent Document 1, deterioration of characteristics or failure sometimes becomes a problem particularly due to heat generation from the functional electrode, and heat dissipation from the shield layer connected to the top surface of the acoustic wave filter, or the like, provides insufficient heat dissipation properties in some cases.

The present disclosure has been made in view of the above point, and intends to provide a high frequency module and a communication device that enable enhancement in heat dissipation properties.

A high frequency module according to an aspect of the present disclosure includes a first mounting board, a first acoustic wave filter, an external connection terminal, a bonding conductor, and a through-conductor. The first mounting board has a first major surface and a second major surface opposite to each other. The first acoustic wave filter is disposed over the first major surface of the first mounting board. The external connection terminal is disposed on the second major surface of the first mounting board. The bonding conductor is disposed between the first major surface of the first mounting board and the first acoustic wave filter. The through-conductor penetrates the first mounting board in the thickness direction of the first mounting board, and is connected to the external connection terminal and the bonding conductor. The first acoustic wave filter has a first substrate and a first functional electrode. The first substrate has a third major surface and a fourth major surface opposite to each other, and includes a piezoelectric body. The first functional electrode is disposed on the third major surface of the first substrate. The fourth major surface of the first substrate is connected to the bonding conductor. The bonding conductor and the through-conductor overlap with the first functional electrode of the first acoustic wave filter in plan view from the thickness direction of the first mounting board.

A communication device according to an aspect of the present disclosure includes the high frequency module and a signal processing circuit. The signal processing circuit is connected to the high frequency module.

With the high frequency module and the communication device according to the above-described aspects of the present disclosure, heat dissipation properties can be enhanced.

### BRIEF DESCRIPTION OF THE DRAWINGS

FIG. 1 is a sectional view of a high frequency module according to embodiment 1;

FIG. 2 is a perspective view of the high frequency module of embodiment 1;

FIG. 3 is a sectional view of a high frequency module according to a modification of embodiment 1;

FIG. 4 is a sectional view of a high frequency module according to embodiment 2;

FIG. 5 is a perspective view of the high frequency module of embodiment 2;

FIG. 6 is a sectional view of a high frequency module according to a modification of embodiment 2;

FIG. 7 is a sectional view of a high frequency module according to embodiment 3;

FIG. 8 is a sectional view of the high frequency module of embodiment 3;

FIG. 9 is a perspective view of the high frequency module of embodiment 3;

FIG. 10 is a sectional view of a high frequency module according to embodiment 4;

FIG. 11 is a perspective view of the high frequency module of embodiment 4;

FIG. 12 is a sectional view of a high frequency module according to embodiment 5;

FIG. 13 is a perspective view of a major part of a high frequency module according to embodiment 6;

FIG. 14 is a plan view of through-conductors of the high frequency module of embodiment 6;

FIG. 15 is a perspective view of a major part of a high frequency module according to modification 1 of embodiment 6;

FIG. 16 is a plan view of the through-conductors of the high frequency module of modification 1 of embodiment 6;

FIG. 17 is a perspective view of a major part of a high frequency module according to modification 2 of embodiment 6;

FIG. 18 is a plan view of the through-conductors of the high frequency module of modification 2 of embodiment 6; and

FIG. 19 is a schematic diagram of a communication device according to embodiment 7.

### DESCRIPTION OF THE EMBODIMENTS

A high frequency module 1 according to embodiments 1 to 6 and a communication device 9 according to embodiment 7 are described below with reference to the drawings. Diagrams to which a reference is made in the following embodiments and the like are schematic diagrams, and the ratio of each of the size and the thickness of the respective constituent elements in the diagrams does not necessarily reflect an actual dimension ratio.

### Embodiment 1

### (1) High Frequency Module

A configuration of the high frequency module 1 according to embodiment 1 is described with reference to drawings.

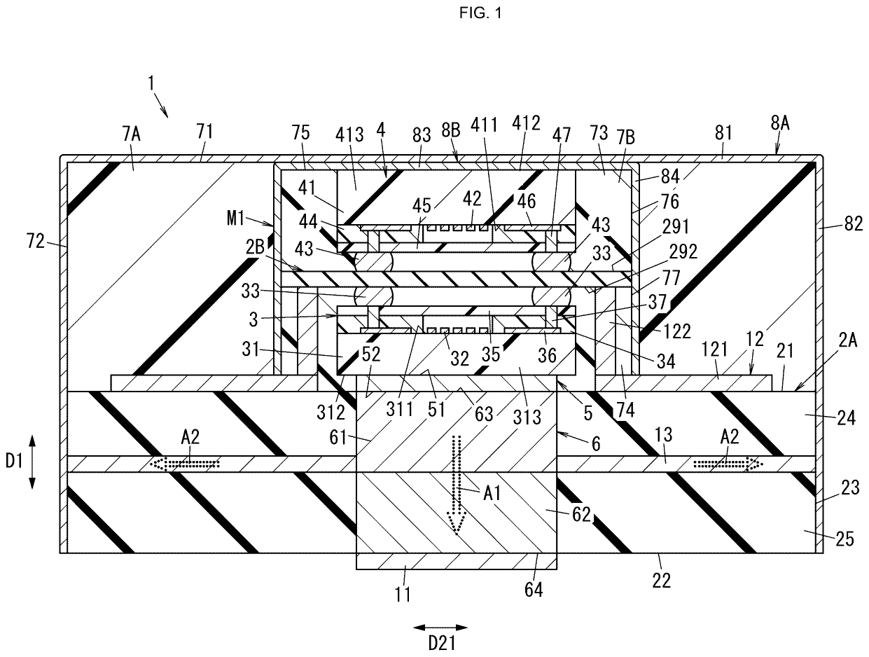

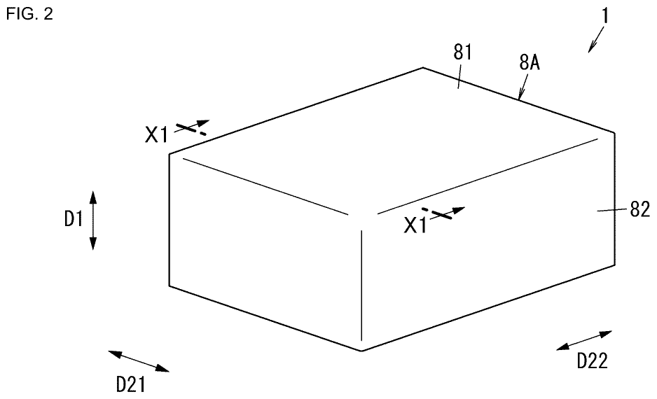

As depicted in FIG. 1, the high frequency module 1 according to embodiment 1 includes a first mounting board 2A, a first acoustic wave filter 3, an external connection terminal 11, a bonding conductor 5, and a through-conductor 6. FIG. 1 is a sectional view along line X1-X1 in FIG. 2.

The first mounting board 2A has a first major surface 21 and a second major surface 22 opposite to each other. The first acoustic wave filter 3 is disposed over the first major surface 21 of the first mounting board 2A. The external connection terminal 11 is disposed on the second major surface 22 of the first mounting board 2A. The bonding conductor 5 is disposed between the first major surface 21 of the first mounting board 2A and the first acoustic wave filter 3. The through-conductor 6 penetrates the first mounting board 2A in a thickness direction D1 of the first mounting board 2A, and is connected to the external connection terminal 11 and the bonding conductor 5.

The first acoustic wave filter 3 has a first substrate 31 and a first functional electrode 32. The first substrate 31 has a third major surface 311 and a fourth major surface 312 opposite to each other, and includes a piezoelectric body 313. The first functional electrode 32 is disposed on the third major surface 311 of the first substrate 31.

The fourth major surface 312 of the first substrate 31 is connected to the bonding conductor 5. The bonding conductor 5 and the through-conductor 6 overlap with the first functional electrode 32 of the first acoustic wave filter 3 in plan view from the thickness direction D1 of the first mounting board 2A.

With the high frequency module 1 according to embodiment 1, it is possible to provide a short path as a heat dissipation path from the first acoustic wave filter 3 disposed over the first major surface 21 of the first mounting board 2A to the external connection terminal 11 disposed on the second major surface 22 of the first mounting board 2A. Thus, effective heat dissipation is enabled.

### (2) Each Constituent Element of High Frequency Module

As depicted in FIGS. 1 and 2, the high frequency module 1 according to embodiment 1 includes the first mounting board 2A, the first acoustic wave filter 3, a second mounting board 2B, a second acoustic wave filter 4, a plurality of (only one piece is depicted in FIG. 1) external connection terminals 11, a first resin member 7A, a first shield layer 8A, the bonding conductor 5, and the through-conductor 6. Further, the high frequency module 1 according to embodiment 1 includes a second resin member 7B and a second shield layer 8B. A module M1 is formed by the second mounting board 2B, the first acoustic wave filter 3, the second acoustic wave filter 4, the second resin member 7B, the second shield layer 8B, and the like.

The high frequency module 1 according to embodiment 1 has a transmitting function of transmitting a high frequency signal (transmission signal) and a receiving function of receiving a high frequency signal (received signal). That is, the high frequency module 1 according to embodiment 1 is a transmitting/receiving module.

Each constituent element of the high frequency module 1 according to embodiment 1 is described below with reference to drawings.

### (2.1) First Mounting Board

As depicted in FIG. 1, the first mounting board 2A has the first major surface 21 and the second major surface 22. The first major surface 21 and the second major surface 22 are opposite to each other. Specifically, the first major surface 21 and the second major surface 22 are opposite to each other in the thickness direction D1 of the first mounting board 2A. The first mounting board 2A is a board for disposing electronic components, and has, for example, a rectangular plate shape. The first major surface 21 and the second major surface 22 are, for example, rectangles. The second major surface 22 is opposite to an external board when the high frequency module 1 is disposed on the external board.

The first mounting board 2A has a plurality of dielectric layers including a first dielectric layer 24 and a second dielectric layer 25 and a plurality of electrically-conductive layers. The first mounting board 2A is, for example, a multilayer substrate having the dielectric layers and the electrically-conductive layers. The dielectric layers and the electrically-conductive layers are laminated in the thickness direction D1 of the first mounting board 2A.

Each of the electrically-conductive layers includes one or multiple conductor portions in one plane orthogonal to the thickness direction D1 of the first mounting board 2A. The electrically-conductive layers are formed into a predetermined pattern defined for each layer. The material of each electrically-conductive layer is, for example, copper.

The electrically-conductive layers include a ground layer 13. The ground layer 13 is a layer set to a ground potential (reference potential), and is disposed inside the first mounting board 2A. When the high frequency module 1 is disposed on an external board (for example, motherboard), the ground layer 13 is connected to a ground of the external board through a via conductor or the like that the first mounting board 2A has, and is kept at the ground potential (reference potential).

The first mounting board 2A is, for example, a low temperature co-fired ceramics (LTCC) substrate. The first mounting board 2A is not limited to the LTCC substrate, and may be, for example, a printed wiring board, a high temperature co-fired ceramics (HTCC) substrate, or a resin multilayer substrate.

### (2.2) First Acoustic Wave Filter

As depicted in FIG. 1, the first acoustic wave filter 3 is disposed over the first major surface 21 of the first mounting board 2A. The first acoustic wave filter 3 of embodiment 1 is disposed over the first major surface 21 of the first mounting board 2A, with the bonding conductor 5 interposed therebetween. Moreover, the first acoustic wave filter 3 of embodiment 1 is disposed over the first major surface 21 of the first mounting board 2A by being disposed on the second mounting board 2B.

The first acoustic wave filter 3 includes the first substrate 31, the first functional electrode 32, a plurality of (only two pieces are depicted in FIG. 1) first connection terminals 33, a support layer 34, a cover layer 35, a plurality of (only two pieces are depicted in FIG. 1) wiring electrodes 36, and a plurality of (only two pieces are depicted in FIG. 1) connection via conductors 37.

The first substrate 31 has the third major surface 311 and the fourth major surface 312, and includes the piezoelectric body 313. The third major surface 311 and the fourth major surface 312 are opposite to each other. Specifically, the third major surface 311 and the fourth major surface 312 are opposite to each other in the thickness direction of the first substrate 31. The thickness direction of the first substrate 31 is a direction along the thickness direction D1 of the first mounting board 2A.

The first substrate 31 of embodiment 1 is a piezoelectric substrate, and is, for example, a lithium tantalate substrate or a lithium niobate substrate.

The first functional electrode 32 is disposed on the third major surface 311 of the first substrate 31. When the first acoustic wave filter 3 is a surface acoustic wave (SAW) filter, the first functional electrode 32 is composed of a plurality of interdigital transducer (IDT) electrodes.

The first connection terminals 33 are connected to a sixth major surface 292 of the second mounting board 2B. Specifically, the first connection terminals 33 are connected to an electrically-conductive layer disposed on the sixth major surface 292 of the second mounting board 2B. The first connection terminals 33 are each connected to the wiring electrode 36 that overlaps in the thickness direction of the first substrate 31 among the plurality of wiring electrodes 36. The first connection terminals 33 are formed into, for example, a circular shape. Each first connection terminal 33 is formed of, for example, a solder. The first connection terminals 33 are exposed from the cover layer 35.

The support layer 34 is disposed on the side of the third major surface 311 of the first substrate 31. The support layer 34 surrounds the first functional electrode 32 in plan view from the thickness direction of the first substrate 31. The support layer 34 has, for example, a rectangular frame shape in plan view from the thickness direction of the first substrate 31. The support layer 34 has electrical insulation properties. The material of the support layer 34 is an epoxy resin, polyimide, or the like.

The cover layer 35 has a flat plate shape. The cover layer 35 is disposed on the support layer 34 in such a manner as to be opposite to the first substrate 31 in the thickness direction of the first substrate 31. The cover layer 35 overlaps with the first functional electrode 32 in the thickness direction of the first substrate 31, and is separate from the first functional electrode 32 in the thickness direction of the first substrate 31. The cover layer 35 has electrical insulation properties. The material of the cover layer 35 is an epoxy resin, polyimide, or the like. The first acoustic wave filter 3 has a space surrounded by the first substrate 31, the support layer 34, and the cover layer 35. A gas exists in the space. The gas is air, an inert gas (for example, nitrogen gas), or the like.

The wiring electrodes 36 are formed on the third major surface 311 of the first substrate 31. The wiring electrodes 36 are connected to the first functional electrode 32.

The connection via conductors 37 couple the first connection terminals 33 to the wiring electrodes 36.

The first acoustic wave filter 3 is disposed on the sixth major surface 292 of the second mounting board 2B by being connected to electrodes disposed on the sixth major surface 292 of the second mounting board 2B through the first connection terminals 33.

### (2.3) Second Mounting Board

As depicted in FIG. 1, the second mounting board 2B has a fifth major surface 291 and the sixth major surface 292. The fifth major surface 291 and the sixth major surface 292 are opposite to each other. Specifically, the fifth major surface 291 and the sixth major surface 292 are opposite to each other in the thickness direction of the second mounting board 2B. The second mounting board 2B is a board for disposing electronic components, and has, for example, a rectangular plate shape. The fifth major surface 291 and the sixth major surface 292 are, for example, rectangles.

The second mounting board 2B has a plurality of dielectric layers and a plurality of electrically-conductive layers. The second mounting board 2B is, for example, a multilayer substrate having the dielectric layers and the electrically-conductive layers. The dielectric layers and the electrically-conductive layers are laminated in the thickness direction of the second mounting board 2B.

Each of the electrically-conductive layers includes one or multiple conductor portions in one plane orthogonal to the thickness direction of the second mounting board 2B. The electrically-conductive layers are formed into a predetermined pattern defined for each layer. The material of each electrically-conductive layer is, for example, copper.

The electrically-conductive layers include a ground layer. The ground layer is a layer set to the ground potential (reference potential), and is disposed inside the second mounting board 2B.

The second mounting board 2B is, for example, an LTCC substrate. The second mounting board 2B is not limited to the LTCC substrate, and may be, for example, a printed wiring board, an HTCC substrate, or a resin multilayer substrate.

The second mounting board 2B is connected to the first mounting board 2A through a plurality of (only two pieces are depicted in FIG. 1) connection members 12. Each of the connection members 12 has a pattern conductor 121 and a via conductor 122. The pattern conductor 121 is disposed on the first major surface 21 of the first mounting board 2A. The via conductor 122 is disposed on the second mounting board 2B, and is connected to the pattern conductor 121.

### (2.4) Second Acoustic Wave Filter

As depicted in FIG. 1, the second acoustic wave filter 4 is disposed on the fifth major surface 291 of the second mounting board 2B.

The second acoustic wave filter 4 includes a second substrate 41, a second functional electrode 42, a plurality of second connection terminals 43, a support layer 44, a cover layer 45, a plurality of wiring electrodes 46, and a plurality of connection via conductors 47.

The second substrate 41 has a seventh major surface 411 and an eighth major surface 412, and includes a piezoelectric body 413. The seventh major surface 411 and the eighth major surface 412 are opposite to each other. Specifically, the seventh major surface 411 and the eighth major surface 412 are opposite to each other in the thickness direction of the second substrate 41. The thickness direction of the second substrate 41 is a direction along the thickness direction D1 of the first mounting board 2A.

The second substrate 41 of embodiment 1 is a piezoelectric substrate, and is, for example, a lithium tantalate substrate or a lithium niobate substrate.

The second functional electrode 42 is disposed on the seventh major surface 411 of the second substrate 41. When the second acoustic wave filter 4 is a SAW filter, the second functional electrode 42 is composed of a plurality of IDT electrodes.

The second connection terminals 43 are disposed on the side of the seventh major surface 411 of the second substrate 41. The second connection terminals 43 are connected to an electrically-conductive layer disposed on the fifth major surface 291 of the second mounting board 2B. The second connection terminals 43 are each connected to the wiring electrode 46 that overlaps in the thickness direction of the second substrate 41 among the plurality of wiring electrodes 46. The second connection terminals 43 are formed into, for example, a circular shape. Each second connection terminal 43 is formed of, for example, a solder. The second connection terminals 43 are exposed from the cover layer 45.

The support layer 44 is disposed on the side of the seventh major surface 411 of the second substrate 41. The support layer 44 surrounds the second functional electrode 42 in plan view from the thickness direction of the second substrate 41. The support layer 44 has, for example, a rectangular frame shape in plan view from the thickness direction of the second substrate 41. The support layer 44 has electrical insulation properties. The material of the support layer 44 is an epoxy resin, polyimide, or the like.

The cover layer 45 has a flat plate shape. The cover layer 45 is disposed on the support layer 44 in such a manner as to be opposite to the second substrate 41 in the thickness direction of the second substrate 41. The cover layer 45 overlaps with the second functional electrode 42 in the thickness direction of the second substrate 41, and is separate from the second functional electrode 42 in the thickness direction of the second substrate 41. The cover layer 45 has electrical insulation properties. The material of the cover layer 45 is an epoxy resin, polyimide, or the like. The second acoustic wave filter 4 has a space surrounded by the second substrate 41, the support layer 44, and the cover layer 45. A gas exists in the space. The gas is air, an inert gas (for example, nitrogen gas), or the like.

The wiring electrodes 46 are formed on the seventh major surface 411 of the second substrate 41. The wiring electrodes 46 are connected to the second functional electrode 42.

The connection via conductors 47 couple the second connection terminals 43 to the wiring electrodes 46.

The second acoustic wave filter 4 is disposed on the fifth major surface 291 of the second mounting board 2B by being connected to electrodes disposed on the fifth major surface 291 of the second mounting board 2B through the second connection terminals 43.

### (2.5) External Connection Terminal

The external connection terminals 11 are disposed on the second major surface 22 of the first mounting board 2A as depicted in FIG. 1. The external connection terminals 11 are terminals for electrically connecting the first mounting board 2A to an external board. The external connection terminals 11 are arranged at intervals from each other on the second major surface 22 of the first mounting board 2A. The external connection terminals 11 are arranged in a matrix along a first direction D21 and a second direction D22 (see FIG. 2) in plan view from the thickness direction D1 of the first mounting board 2A.

The external connection terminals 11 are each an electrically-conductive member with a flat plate shape. The material of the external connection terminals 11 is, for example, a metal (for example, copper, copper alloy, or the like).

Each external connection terminal 11 is connected to an external connection electrode of the external board. In the present specification and the like, the expression “the external connection terminal 11 is connected to an external connection electrode of an external board” does not only refer to contact between the external connection terminal 11 and the external connection terminal of the external board but also includes electrical connection between the external connection terminal 11 and the external connection terminal of the external board through a conductor electrode, a conductor terminal, a wiring line, another circuit component, or the like. The external connection terminals 11 are connected to the external connection electrode of the external board through, for example, a connection member (for example, solder bump) formed of a conductor.

### (2.6) First Resin Member

As depicted in FIG. 1, the first resin member 7A is disposed on the first major surface 21 of the first mounting board 2A. The first resin member 7A contains a resin and a filler. The resin is, for example, an epoxy resin. The first resin member 7A is in contact with the first major surface 21 of the first mounting board 2A, and covers at least part of the module M1. That is, the first resin member 7A covers at least part of the first acoustic wave filter 3. This can protect the first mounting board 2A and the module M1 (first acoustic wave filter 3).

### (2.7) First Shield Layer

As depicted in FIG. 1, the first shield layer 8A covers a side surface 72 of the first resin member 7A and at least part of the first mounting board 2A. Specifically, the first shield layer 8A covers a top surface 71 and the side surface 72 of the first resin member 7A and a side surface 23 of the first mounting board 2A. The top surface 71 of the first resin member 7A is a major surface on the opposite side to the side of the first mounting board 2A in the first resin member 7A.

The first shield layer 8A has a top surface portion 81 and a side surface portion 82. The top surface portion 81 covers the top surface 71 of the first resin member 7A. The side surface portion 82 is formed to protrude from the outer edge of the top surface portion 81, and covers the side surface 72 of the first resin member 7A and the side surface 23 of the first mounting board 2A.

The first shield layer 8A has electrical conductivity. Specifically, the first shield layer 8A has a multilayer structure obtained by laminating metal layers. The metal layers contain one or multiple kinds of metals. The first shield layer 8A is not limited to the above-described multilayer structure, and may be one metal layer.

The first shield layer 8A is disposed, for example, for the purpose of an electromagnetic shield between the inside and the outside of the high frequency module 1. The first shield layer 8A is in contact with at least part of the ground layer 13 of the first mounting board 2A. This allows the potential of the first shield layer 8A to become the same as the potential of the ground layer 13.

### (2.8) Ground Layer

As depicted in FIG. 1, the ground layer 13 is disposed inside the first mounting board 2A, and is connected to the through-conductor 6.

In the high frequency module 1 according to embodiment 1, at least part of the ground layer 13 is exposed in the side surface 23 of the first mounting board 2A, and is connected to the first shield layer 8A.

### (2.9) Second Resin Member

As depicted in FIG. 1, the second resin member 7B includes a first resin portion 73 and a second resin portion 74.

The first resin portion 73 is disposed on the fifth major surface 291 of the second mounting board 2B. The first resin portion 73 contains a resin and a filler. The resin is, for example, an epoxy resin. The first resin portion 73 is in contact with the fifth major surface 291 of the second mounting board 2B, and covers at least part of the second acoustic wave filter 4. This can protect the second mounting board 2B and the second acoustic wave filter 4. The second resin portion 74 is disposed on the sixth major surface 292 of the second mounting board 2B. The second resin portion 74 contains a resin and a filler. The resin is, for example, an epoxy resin. The second resin portion 74 is in contact with the sixth major surface 292 of the second mounting board 2B, and covers at least part of the first acoustic wave filter 3. This can protect the second mounting board 2B and the first acoustic wave filter 3.

### (2.10) Second Shield Layer

As depicted in FIG. 1, the second shield layer 8B covers side surfaces 76 and 77 of the second resin member 7B and at least part of the second mounting board 2B. Specifically, the second shield layer 8B covers a top surface 75 and the side surfaces 76 and 77 of the second resin member 7B and a side surface of the second mounting board 2B. The top surface 75 of the second resin member 7B is a major surface on the opposite side to the side of the second mounting board 2B in the second resin member 7B.

The second shield layer 8B has a top surface portion 83 and a side surface portion 84. The top surface portion 83 covers the top surface 75 of the second resin member 7B. The side surface portion 84 is formed to protrude from the outer edge of the top surface portion 83, and covers the side surfaces 76 and 77 of the second resin member 7B and the side surface of the second mounting board 2B.

The second shield layer 8B is connected to the eighth major surface 412 of the second substrate 41. In other words, the eighth major surface 412 of the second substrate 41 is connected to the second shield layer 8B.

The second shield layer 8B has electrical conductivity. Specifically, the second shield layer 8B has a multilayer structure obtained by laminating metal layers. The metal layers contain one or multiple kinds of metals. The second shield layer 8B is not limited to the above-described multilayer structure, and may be one metal layer.

The second shield layer 8B is disposed, for example, for the purpose of an electromagnetic shield between the inside and the outside of the high frequency module 1. The second shield layer 8B is in contact with at least part of the ground layer of the second mounting board 2B. This allows the potential of the second shield layer 8B to become the same as the potential of the ground layer.

### (2.11) Bonding Conductor

As depicted in FIG. 1, the bonding conductor 5 is disposed between the first major surface 21 of the first mounting board 2A and the first acoustic wave filter 3. The bonding conductor 5 is disposed on the first major surface 21 of the first mounting board 2A. Specifically, the bonding conductor 5 is disposed on the first major surface 21 of the first mounting board 2A in such a manner as to overlap with the position at which the through-conductor 6 is formed in the first mounting board 2A in plan view from the thickness direction D1 of the first mounting board 2A. The material of the bonding conductor 5 has a high thermal and electrical conductivity, e.g., silver.

The bonding conductor 5 has major surfaces 51 and 52. The major surface 51 and the major surface 52 are opposite to each other. Specifically, the major surface 51 and the major surface 52 are opposite to each other in the thickness direction D1 of the first mounting board 2A.

The bonding conductor 5 is connected to the fourth major surface 312 of the first substrate 31 in the first acoustic wave filter 3. In other words, the fourth major surface 312 of the first substrate 31 is connected to the bonding conductor 5.

### (2.12) Through-Conductor

As depicted in FIG. 1, the through-conductor 6 penetrates the first mounting board 2A in the thickness direction D1 of the first mounting board 2A, and is connected to the external connection terminal 11 and the bonding conductor 5.

The through-conductor 6 has a first via conductor 61 and a second via conductor 62. The first via conductor 61 is disposed to penetrate the first dielectric layer 24 in the first dielectric layer 24 of the first mounting board 2A. The second via conductor 62 is disposed to penetrate the second dielectric layer 25 in the second dielectric layer 25 of the first mounting board 2A.

The through-conductor 6 has a plurality of major surfaces 63 and 64. The major surface 63 and the major surface 64 are opposite to each other. Specifically, the major surface 63 and the major surface 64 are opposite to each other in the thickness direction D1 of the first mounting board 2A. The through-conductor 6 is connected to the bonding conductor 5 at the major surface 63. Further, the through-conductor 6 is connected to the external connection terminal 11 at the major surface 64.

The bonding conductor 5 and the through-conductor 6 overlap with the first functional electrode 32 of the first acoustic wave filter 3 in plan view from the thickness direction D1 of the first mounting board 2A. This vertical alignment of the first functional electrode 32, the first substrate 31, the bonding conductor 5, the through-conductor 6, and the external connection terminal 11 forms a primary thermally conductive path for dissipating heat generated by the first functional electrode 32 during operation. Instead of relying on heat dissipation from the top surface of the filter to a shield layer, the present disclosure provides a significantly shorter and more thermally conductive path through the mounting board itself, directly addressing the issue of heat accumulation at the functional electrode.

### (3) Heat Dissipation of High Frequency Module

Next, heat dissipation of the high frequency module 1 according to embodiment 1 is described with reference to FIG. 1.

Heat generated by the first functional electrode 32 of the first acoustic wave filter 3 passes through the first substrate 31 and is dissipated to the bonding conductor 5. The heat dissipated to the bonding conductor 5 is dissipated to the through-conductor 6, and is conducted in the through-conductor 6 as indicated by an arrow A1 to be released to the external of the high frequency module 1.

Moreover, in embodiment 1, the heat transmitted to the through-conductor 6 is conducted to the ground layer 13 as indicated by arrows A2, and is released to the external of the high frequency module 1.

This can dissipate the heat from the first acoustic wave filter 3 by the short heat dissipation path.

The first acoustic wave filter 3 allows a transmission signal to path through the first acoustic wave filter 3. The second acoustic wave filter 4 allows a received signal to pass through the second acoustic wave filter 4.

Due to this, the first acoustic wave filter 3, which allows the transmission signal to pass therethrough, has a higher heat dissipation effect than the second acoustic wave filter 4, and the first acoustic wave filter 3 is connected to the bonding conductor 5 and the through-conductor 6. Thus, the heat dissipation effect can be enhanced.

### (4) Effects

With the high frequency module 1 according to embodiment 1, it is possible to provide a short path as a heat dissipation path from the first acoustic wave filter 3 disposed over the first major surface 21 of the first mounting board 2A to the external connection terminal 11 disposed on the second major surface 22 of the first mounting board 2A. Thus, effective heat dissipation is enabled.

With the high frequency module 1 according to embodiment 1, heat can be dissipated through the bonding conductor 5, the through-conductor 6, the ground layer 13, and the first shield layer 8A, and thus more effective heat dissipation is enabled.

With the high frequency module 1 according to embodiment 1, more effective heat dissipation is enabled even when the first acoustic wave filter 3 and the second acoustic wave filter 4 are disposed on the second mounting board 2B.

With the high frequency module 1 according to embodiment 1, heat from the second acoustic wave filter 4 can be dissipated from the second shield layer 8B.

With the high frequency module 1 according to embodiment 1, the heat dissipation effect can be enhanced because the first acoustic wave filter 3 that allows the transmission signal to pass therethrough has a higher heat dissipation effect than the second acoustic wave filter 4 and the first acoustic wave filter 3 is connected to the bonding conductor 5 and the through-conductor 6.

### (5) Modification

A modification of embodiment 1 is described below.

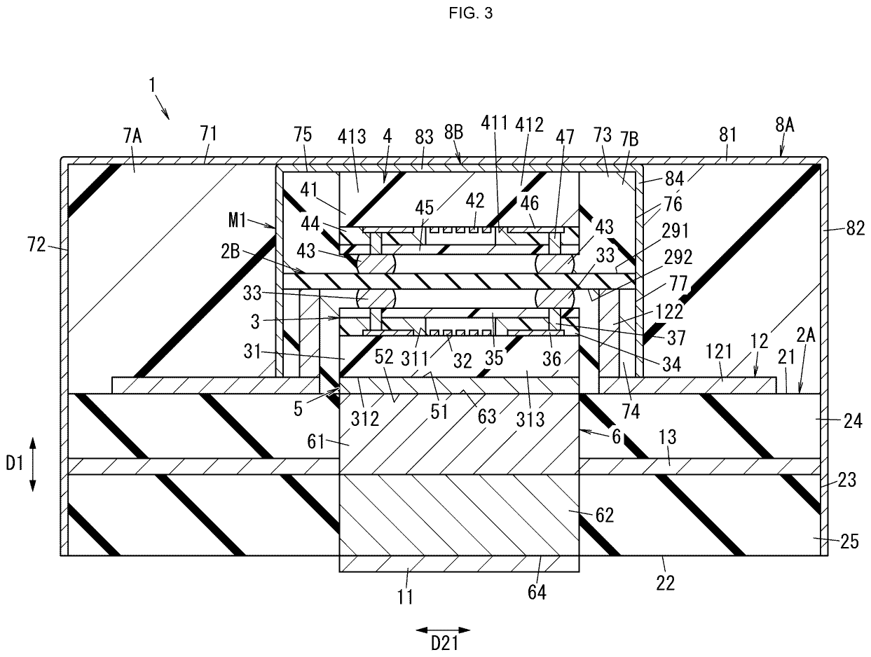

In the high frequency module 1 according to the modification of embodiment 1, as depicted in FIG. 3, the bonding conductor 5 overlaps with the whole of the fourth major surface 312 of the first substrate 31 of the first acoustic wave filter 3 in plan view from the thickness direction D1 of the first mounting board 2A.

With the high frequency module 1 according to the modification of embodiment 1, the contact area between the bonding conductor 5 and the fourth major surface 312 of the first substrate 31 of the first acoustic wave filter 3 can be increased, and thus more effective heat dissipation is enabled.

The high frequency module 1 according to the above-described modification also provides effects similar to those of the high frequency module 1 according to embodiment 1.

### Embodiment 2

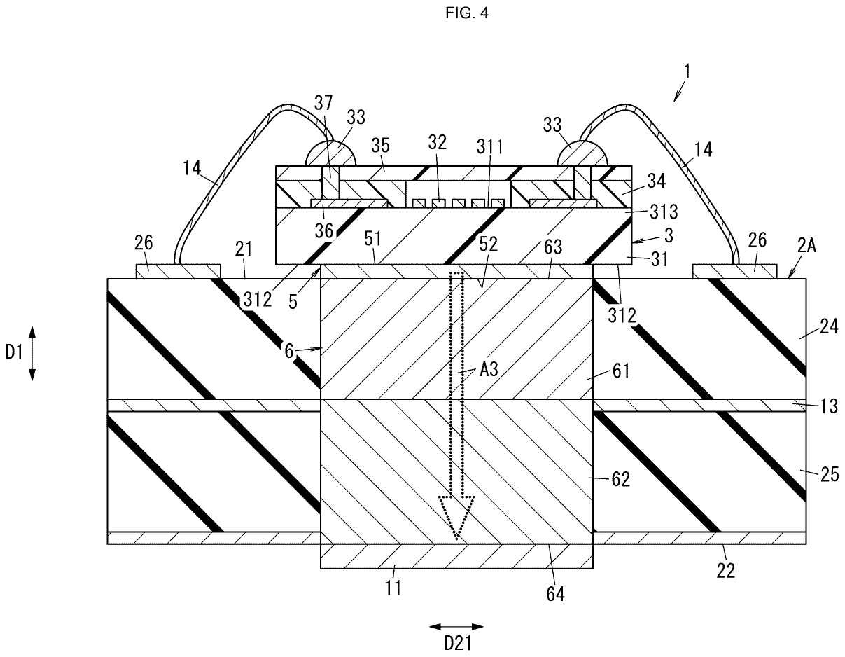

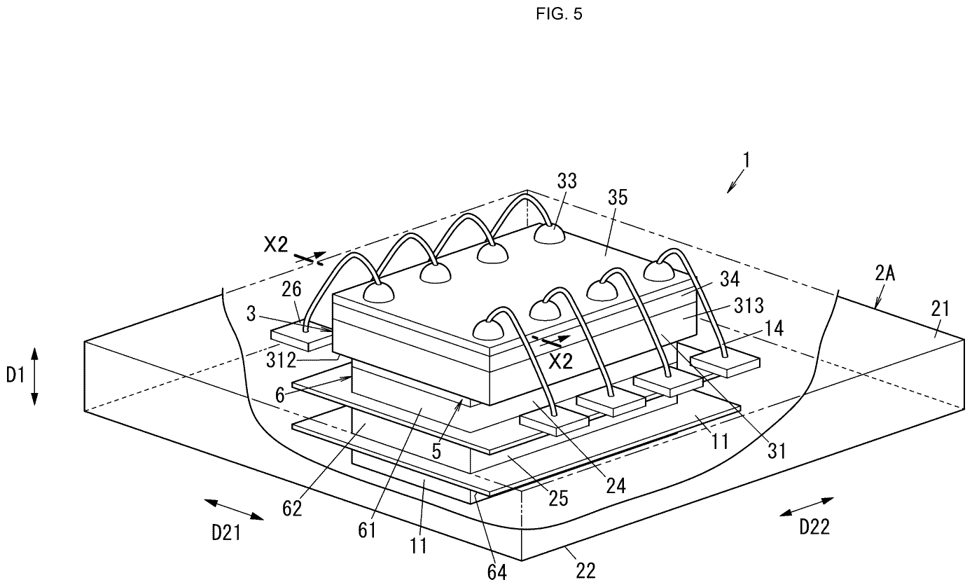

As depicted in FIGS. 4 and 5, the high frequency module 1 according to embodiment 2 is different from the high frequency module 1 according to embodiment 1 (see FIG. 1) in that the first acoustic wave filter 3 is electrically connected to the first mounting board 2A by wire bonding. Concerning the high frequency module 1 according to embodiment 2, a constituent element similar to that of the high frequency module 1 according to embodiment 1 is given the same numeral and description thereof is omitted. FIG. 4 is a sectional view along line X2-X2 in FIG. 5.

### (1) Configuration

As depicted in FIGS. 4 and 5, the high frequency module 1 according to embodiment 2 includes the first mounting board 2A, the first acoustic wave filter 3, a plurality of (only one piece is depicted in FIG. 4) external connection terminals 11, the bonding conductor 5, and the through-conductor 6.

The first mounting board 2A of embodiment 2 further has a plurality of (only two pieces are depicted in FIG. 4) signal terminals 26 as depicted in FIGS. 4 and 5. The signal terminals 26 are disposed on the first major surface 21 of the first mounting board 2A. Concerning the first mounting board 2A of embodiment 2, description is omitted regarding configurations and functions similar to those of the first mounting board 2A of embodiment 1 (see FIG. 1).

The first acoustic wave filter 3 of embodiment 2 has the first substrate 31, the first functional electrode 32, a plurality of (only two pieces are depicted in FIG. 4) first connection terminals 33, the support layer 34, the cover layer 35, a plurality of (only two pieces are depicted in FIG. 4) wiring electrodes 36, and a plurality of (only two pieces are depicted in FIG. 4) connection via conductors 37. Concerning the first acoustic wave filter 3 of embodiment 2, description is omitted regarding configurations and functions similar to those of the first acoustic wave filter 3 of embodiment 1 (see FIG. 1).

The first substrate 31 has the third major surface 311 and the fourth major surface 312, and includes the piezoelectric body 313. The third major surface 311 and the fourth major surface 312 are opposite to each other. Specifically, the third major surface 311 and the fourth major surface 312 are opposite to each other in the thickness direction of the first substrate 31. The thickness direction of the first substrate 31 is a direction along the thickness direction D1 of the first mounting board 2A.

The first substrate 31 of embodiment 2 is a piezoelectric substrate, and is, for example, a lithium tantalate substrate or a lithium niobate substrate.

The first functional electrode 32 is disposed on the third major surface 311 of the first substrate 31. When the first acoustic wave filter 3 is a SAW filter, the first functional electrode 32 is composed of a plurality of IDT electrodes.

Each of the first connection terminals 33 is connected to a corresponding one of the signal terminals 26 through a bonding wire 14. The first connection terminals 33 are each connected to the wiring electrode 36 that overlaps in the thickness direction of the first substrate 31 among the plurality of wiring electrodes 36. The first connection terminals 33 are formed into, for example, a circular shape. Each first connection terminal 33 is formed of, for example, a solder. The first connection terminals 33 are exposed from the cover layer 35.

The support layer 34 is disposed on the side of the third major surface 311 of the first substrate 31. The support layer 34 surrounds the first functional electrode 32 in plan view from the thickness direction of the first substrate 31. The support layer 34 has, for example, a rectangular frame shape in plan view from the thickness direction of the first substrate 31. The support layer 34 has electrical insulation properties. The material of the support layer 34 is an epoxy resin, polyimide, or the like. The cover layer 35 has a flat plate shape. The cover layer 35 is disposed on the support layer 34 in such a manner as to be opposite to the first substrate 31 in the thickness direction of the first substrate 31. The cover layer 35 overlaps with the first functional electrode 32 in the thickness direction of the first substrate 31, and is separate from the first functional electrode 32 in the thickness direction of the first substrate 31. The cover layer 35 has electrical insulation properties. The material of the cover layer 35 is an epoxy resin, polyimide, or the like. The first acoustic wave filter 3 has a space surrounded by the first substrate 31, the support layer 34, and the cover layer 35. A gas exists in the space. The gas is air, an inert gas (for example, nitrogen gas), or the like.

The wiring electrodes 36 are formed on the third major surface 311 of the first substrate 31. The wiring electrodes 36 are connected to the first functional electrode 32.

The connection via conductors 37 couple the first connection terminals 33 to the wiring electrodes 36.

The first acoustic wave filter 3 of embodiment 2 is disposed over the first major surface 21 of the first mounting board 2A by being connected to the signal terminals 26 disposed on the first major surface 21 of the first mounting board 2A through the first connection terminals 33.

### (2) Heat Dissipation

Next, heat dissipation of the high frequency module 1 according to embodiment 2 is described with reference to FIG. 4.

Heat generated by the first functional electrode 32 of the first acoustic wave filter 3 passes through the first substrate 31 and is dissipated to the bonding conductor 5. As depicted in FIG. 4, the heat dissipated to the bonding conductor 5 is dissipated to the through-conductor 6, and is conducted in the through-conductor 6 as indicated by an arrow A3 to be released to the external of the high frequency module 1.

This can dissipate the heat from the first acoustic wave filter 3 by the short heat dissipation path.

### (3) Effects

With the high frequency module 1 according to embodiment 2, effective heat dissipation is enabled even when the first connection terminal 33 of the first acoustic wave filter 3 is connected to the signal terminal 26 of the first mounting board 2A through the bonding wire 14.

### (4) Modification

A modification of embodiment 2 is described below.

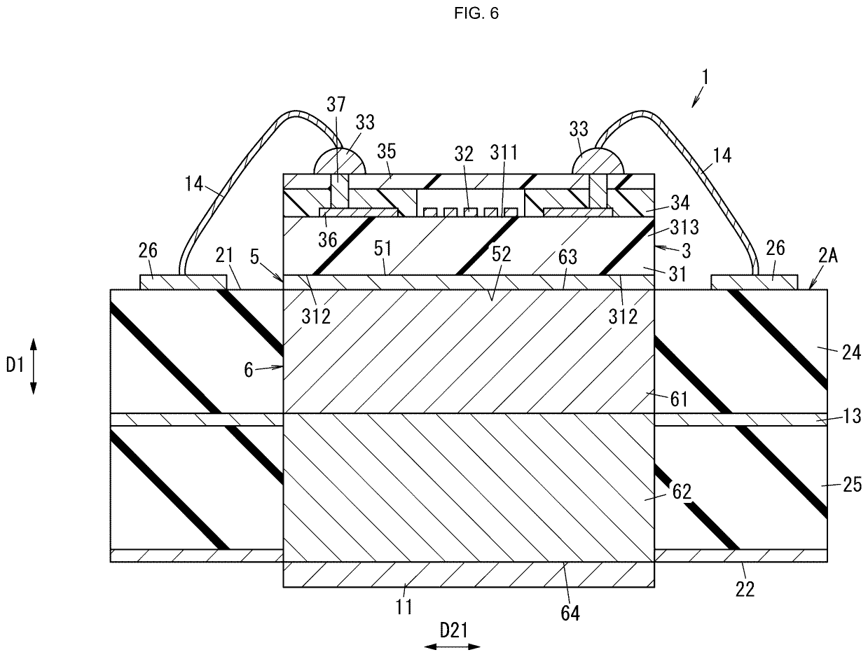

In the high frequency module 1 according to the modification of embodiment 2, as depicted in FIG. 6, the bonding conductor 5 overlaps with the whole of the fourth major surface 312 of the first substrate 31 of the first acoustic wave filter 3 in plan view from the thickness direction D1 of the first mounting board 2A.

With the high frequency module 1 according to the modification of embodiment 2, the contact area between the bonding conductor 5 and the fourth major surface 312 of the first substrate 31 of the first acoustic wave filter 3 can be increased, and thus more effective heat dissipation is enabled.

The high frequency module 1 according to the above-described modification also provides effects similar to those of the high frequency module 1 according to embodiment 2.

### Embodiment 3

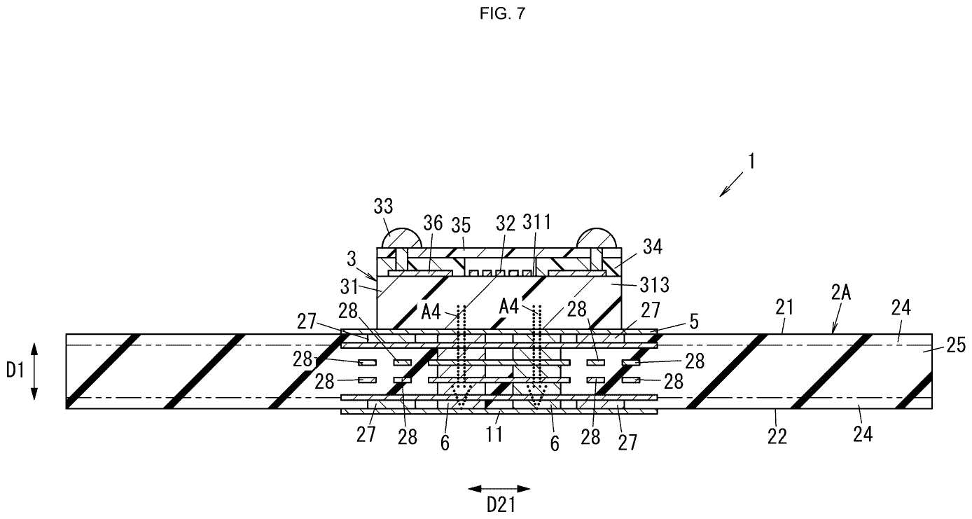

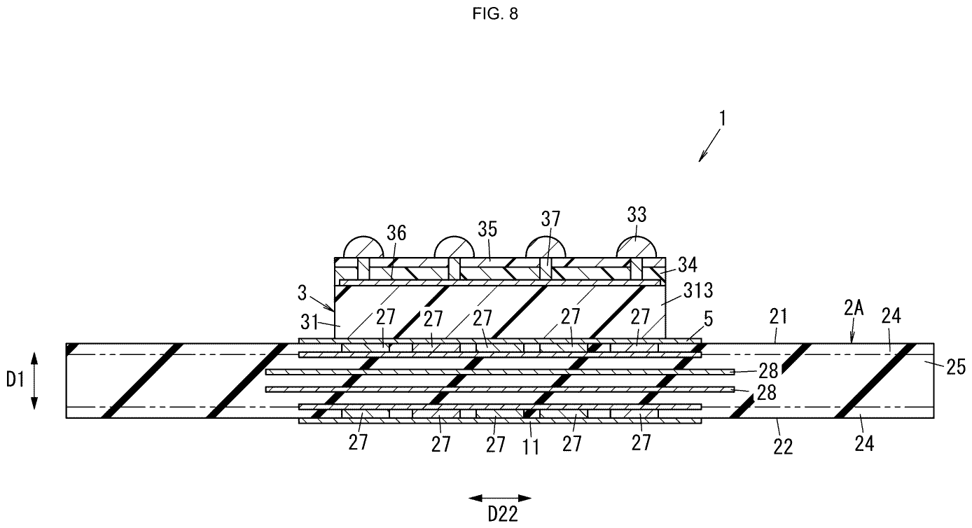

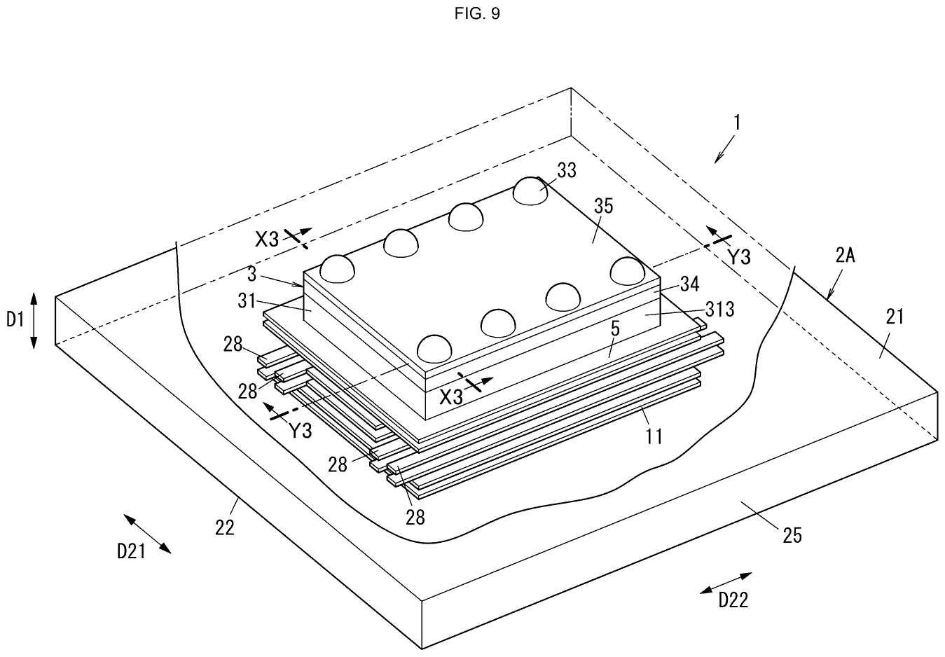

As depicted in FIGS. 7 and 9, the high frequency module 1 according to embodiment 3 is different from the high frequency module 1 according to embodiment 1 (see FIG. 1) in that a wiring conductor 28 is disposed close to the through-conductor 6. Concerning the high frequency module 1 according to embodiment 3, a constituent element similar to that of the high frequency module 1 according to embodiment 1 is given the same numeral and description thereof is omitted. FIG. 7 is a sectional view along line X3-X3 in FIG. 9. FIG. 8 is a sectional view along line Y3-Y3 in FIG. 9.

### (1) Configuration

As depicted in FIGS. 7 to 9, the high frequency module 1 according to embodiment 3 includes the first mounting board 2A, the first acoustic wave filter 3, a plurality of (only one piece is depicted in FIG. 7) external connection terminals 11, the bonding conductor 5, and the through-conductor 6.

As depicted in FIGS. 7 to 9, the first mounting board 2A of embodiment 3 has a plurality of (in the example of FIG. 7, two) first dielectric layers 24, the second dielectric layer 25, a plurality of via conductors 27, and a plurality of wiring conductors 28. The second dielectric layer 25 is located between the first dielectric layers 24. Concerning the first mounting board 2A of embodiment 3, description is omitted regarding configurations and functions similar to those of the first mounting board 2A of embodiment 1 (see FIG. 1).

The via conductors 27 penetrate the first dielectric layer 24. The material of the via conductors 27 is, for example, copper.

The via conductors 27 do not overlap with the first functional electrode 32 of the first acoustic wave filter 3 in the thickness direction D1 of the first mounting board 2A. The via conductors 27 are disposed in the first dielectric layer 24 in such a manner as to be adjacent to the through-conductor 6 in the first direction D21.

The wiring conductors 28 are disposed in the second dielectric layer 25. The material of the wiring conductors 28 is, for example, copper.

The wiring conductors 28 each overlap with the corresponding via conductor 27 among the plurality of via conductors 27 in the thickness direction D1 of the first mounting board 2A. The wiring conductors 28 are disposed in the second dielectric layer 25 in such a manner as to be adjacent to the through-conductor 6 in the first direction D21.

Due to the above-described disposition relationship, the wiring conductor 28 can be disposed at a different position from the through-conductor 6. Thus, the region overlapping with the first acoustic wave filter 3 in the thickness direction D1 of the first mounting board 2A in the first mounting board 2A can be effectively utilized.

### (2) Heat Dissipation

Next, heat dissipation of the high frequency module 1 according to embodiment 3 is described with reference to FIG. 7.

Heat generated by the first functional electrode 32 of the first acoustic wave filter 3 passes through the first substrate 31 and is dissipated to the bonding conductor 5. The heat dissipated to the bonding conductor 5 is dissipated to the through-conductor 6, and is conducted in the through-conductor 6 as indicated by arrows A4 to be released to the external of the high frequency module 1.

This can dissipate the heat from the first acoustic wave filter 3 by the short heat dissipation path.

### (3) Effects

With the high frequency module 1 according to embodiment 3, the wiring conductor 28 can be disposed at a different position from the through-conductor 6. Thus, the region overlapping with the first acoustic wave filter 3 in the thickness direction D1 of the first mounting board 2A in the first mounting board 2A can be effectively utilized. As a result, size reduction including the wiring conductor 28 can be achieved.

### Embodiment 4

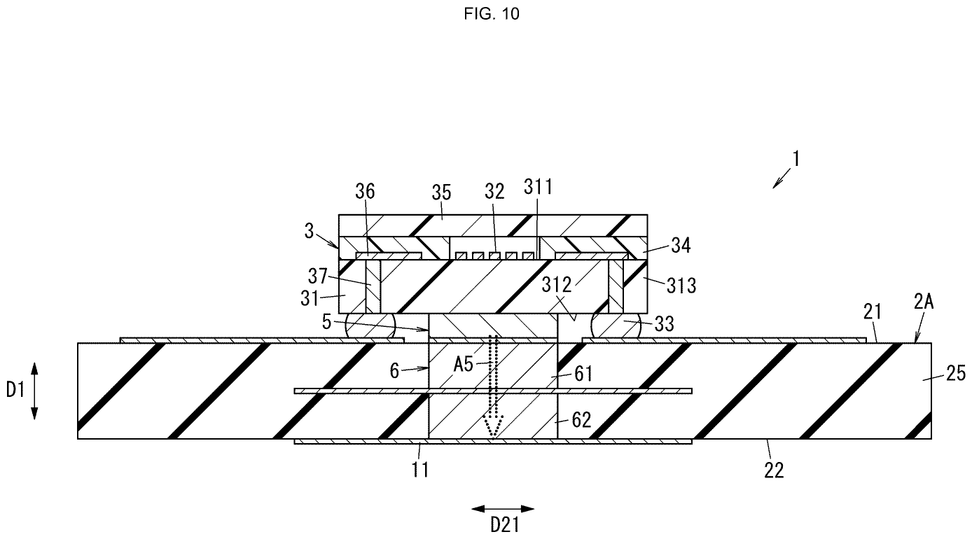

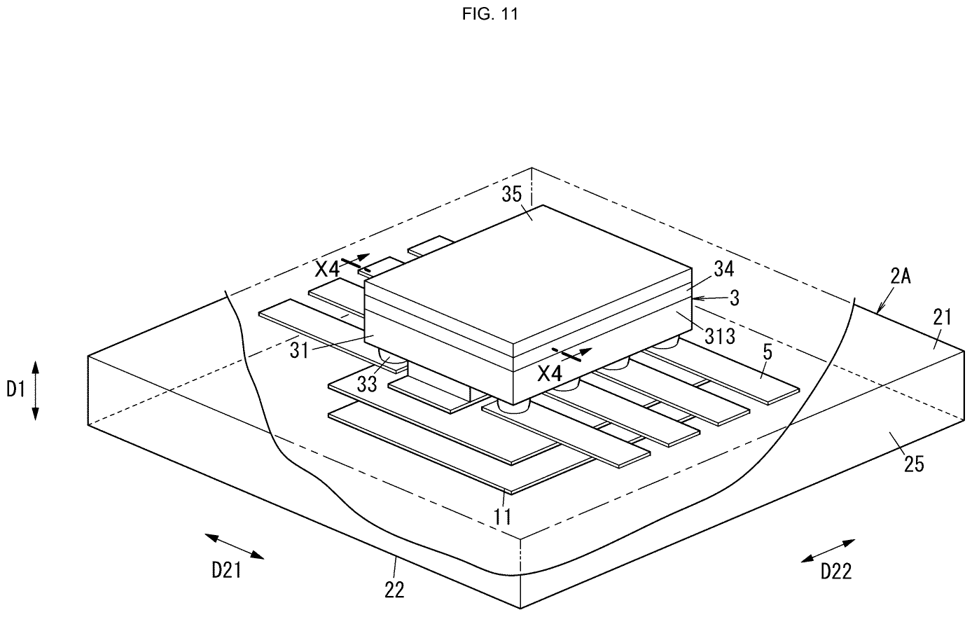

As depicted in FIGS. 10 and 11, the high frequency module 1 according to embodiment 4 is different from the high frequency module 1 according to embodiment 1 (see FIG. 1) in that the first functional electrode 32 of the first acoustic wave filter 3 is located on the opposite side to the first mounting board 2A. Concerning the high frequency module 1 according to embodiment 4, a constituent element similar to that of the high frequency module 1 according to embodiment 1 is given the same numeral and description thereof is omitted. FIG. 10 is a sectional view along line X4-X4 in FIG. 11.

### (1) Configuration

As depicted in FIGS. 10 and 11, the high frequency module 1 according to embodiment 4 includes the first mounting board 2A, the first acoustic wave filter 3, a plurality of (only one piece is depicted in FIG. 10) external connection terminals 11, the bonding conductor 5, and the through-conductor 6.

The first acoustic wave filter 3 of embodiment 4 has a configuration in which the first functional electrode 32 is located on the opposite side to the first mounting board 2A. Concerning the first acoustic wave filter 3 of embodiment 4, description is omitted regarding configurations and functions similar to those of the first acoustic wave filter 3 of embodiment 1 (see FIG. 1).

The first acoustic wave filter 3 of embodiment 4 has the first substrate 31, the first functional electrode 32, a plurality of (only two pieces are depicted in FIG. 10) first connection terminals 33, the support layer 34, the cover layer 35, a plurality of (only two pieces are depicted in FIG. 10) wiring electrodes 36, and a plurality of (only two pieces are depicted in FIG. 10) connection via conductors 37. Concerning the first acoustic wave filter 3 of embodiment 4, description is omitted regarding configurations and functions similar to those of the first acoustic wave filter 3 of embodiment 1 (see FIG. 1).

The first substrate 31 has the third major surface 311 and the fourth major surface 312, and includes the piezoelectric body 313. The third major surface 311 and the fourth major surface 312 are opposite to each other. Specifically, the third major surface 311 and the fourth major surface 312 are opposite to each other in the thickness direction of the first substrate 31. The thickness direction of the first substrate 31 is a direction along the thickness direction D1 of the first mounting board 2A.

The first functional electrode 32 is disposed on the third major surface 311 of the first substrate 31. When the first acoustic wave filter 3 is a SAW filter, the first functional electrode 32 is composed of a plurality of IDT electrodes.

The first connection terminals 33 are connected to the first major surface 21 of the first mounting board 2A. The first connection terminals 33 are each connected to the wiring electrode 36 that overlaps in the thickness direction of the first substrate 31 among the plurality of wiring electrodes 36. The first connection terminals 33 are formed into, for example, a circular shape. Each first connection terminal 33 is formed of, for example, a solder. The first connection terminals 33 are exposed from the fourth major surface 312 of the first substrate 31.

The support layer 34 is disposed on the side of the third major surface 311 of the first substrate 31. The support layer 34 surrounds the first functional electrode 32 in plan view from the thickness direction of the first substrate 31. The support layer 34 has, for example, a rectangular frame shape in plan view from the thickness direction of the first substrate 31. The support layer 34 has electrical insulation properties. The material of the support layer 34 is an epoxy resin, polyimide, or the like.

The cover layer 35 has a flat plate shape. The cover layer 35 is disposed on the support layer 34 in such a manner as to be opposite to the first substrate 31 in the thickness direction of the first substrate 31. The cover layer 35 overlaps with the first functional electrode 32 in the thickness direction of the first substrate 31, and is separate from the first functional electrode 32 in the thickness direction of the first substrate 31. The cover layer 35 has electrical insulation properties. The material of the cover layer 35 is an epoxy resin, polyimide, or the like. The first acoustic wave filter 3 has a space surrounded by the first substrate 31, the support layer 34, and the cover layer 35. A gas exists in the space. The gas is air, an inert gas (for example, nitrogen gas), or the like.

The wiring electrodes 36 are formed on the third major surface 311 of the first substrate 31. The wiring electrodes 36 are connected to the first functional electrode 32.

The connection via conductors 37 couple the first connection terminals 33 to the wiring electrodes 36.

### (2) Heat Dissipation

Next, heat dissipation of the high frequency module 1 according to embodiment 4 is described with reference to FIG. 10.

Heat generated by the first functional electrode 32 of the first acoustic wave filter 3 passes through the first substrate 31 and is dissipated to the bonding conductor 5. The heat dissipated to the bonding conductor 5 is dissipated to the through-conductor 6, and is conducted in the through-conductor 6 as indicated by an arrow A5 to be released to the external of the high frequency module 1.

This can dissipate the heat from the first acoustic wave filter 3 by the short heat dissipation path.

### (3) Effects

With the high frequency module 1 according to embodiment 4, it is possible to provide a short path as a heat dissipation path from the first acoustic wave filter 3 disposed over the first major surface 21 of the first mounting board 2A to the external connection terminal 11 disposed on the second major surface 22 of the first mounting board 2A similarly to the high frequency module 1 of embodiment 1. Further, as may be seen therein 1, the surface area of the external connection terminal 11 on the second major surface 22 is larger than the cross-sectional area of the through-conductor 6 where it connects to the terminal. This larger surface area allows the external connection terminal 11 to also function as a heat spreader, efficiently distributing thermal energy over a wider area for improved transfer to an external board. Thus, effective heat dissipation is enabled.

### Embodiment 5

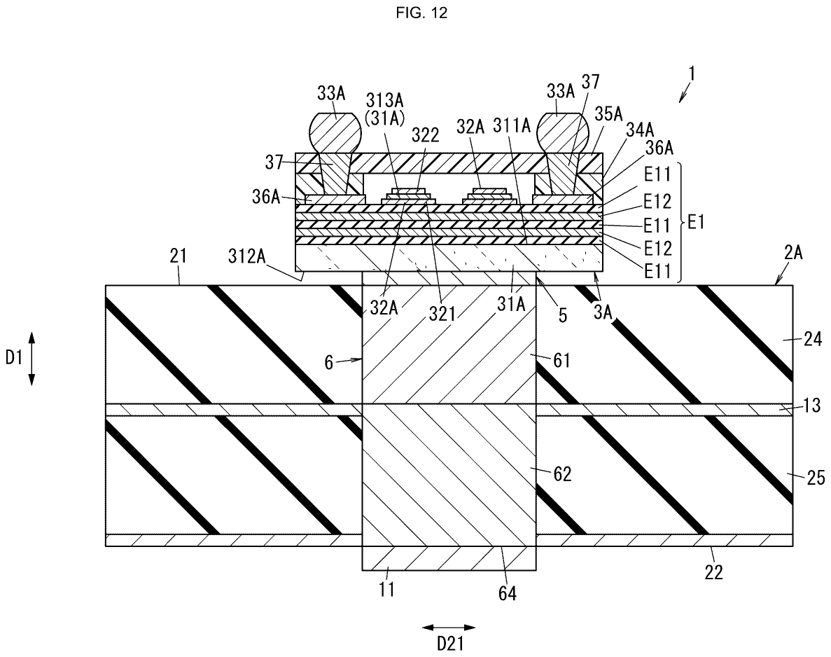

As depicted in FIG. 12, the high frequency module 1 according to embodiment 5 is different from the high frequency module 1 according to embodiment 1 (see FIG. 1) in that the high frequency module 1 according to embodiment 5 includes a first acoustic wave filter 3A. Concerning the high frequency module 1 according to embodiment 5, a constituent element similar to that of the high frequency module 1 according to embodiment 1 is given the same numeral and description thereof is omitted.

### (1) Configuration

As depicted in FIG. 12, the high frequency module 1 according to embodiment 5 includes the first mounting board 2A, the first acoustic wave filter 3A, a plurality of (only one piece is depicted in FIG. 12) external connection terminals 11, the first shield layer 8A, the bonding conductor 5, and the through-conductor 6.

As depicted in FIG. 12, the first acoustic wave filter 3A of embodiment 5 includes a first substrate 31A, a first functional electrode 32A, a plurality of (only two pieces are depicted in FIG. 12) first connection terminals 33A, a support layer 34A, a cover layer 35A, a plurality of (only two pieces are depicted in FIG. 12) wiring electrodes 36A, and a plurality of (only two pieces are depicted in FIG. 12) connection via conductors 37. Further, the first acoustic wave filter 3A includes an acoustic reflection layer E1. Concerning the first acoustic wave filter 3A of embodiment 5, description is omitted regarding configurations and functions similar to those of the first acoustic wave filter 3 of embodiment 1 (see FIG. 1).

The first substrate 31A has a third major surface 311A and a fourth major surface 312A. The third major surface 311A and the fourth major surface 312A are opposite to each other. Specifically, the third substrate 311A and the fourth major surface are opposite to each other in the thickness direction of the first substrate 31A. The thickness direction of the first substrate 31A is a direction along the thickness direction D1 of the first mounting board 2A.

In the first acoustic wave filter 3A, a piezoelectric body 313A is disposed between a first electrode 321 and a second electrode 322.

The acoustic reflection layer E1 is disposed on the third major surface 311A of the first substrate 31A. A plurality of first electrodes 321 are disposed on the acoustic reflection layer E1. The acoustic reflection layer E1 has at least one (for example, three) low acoustic impedance layer E11 and at least one (for example, two) high acoustic impedance layer E12. The acoustic impedance is lower in the low acoustic impedance layer E11 than in the high acoustic impedance layer E12. The first acoustic wave filter 3A is a solidly mounted resonator (SMR). The material of the high acoustic impedance layers E12 is, for example, platinum. The material of the low acoustic impedance layers E11 is, for example, silicon oxide. The material of the high acoustic impedance layers E12 is not limited to platinum, and may be a metal such as, for example, tungsten or tantalum. The material of the high acoustic impedance layers E12 is not limited to the metal, and may be, for example, an insulator. The high acoustic impedance layers E12 are not limited to the case in which they are composed of the same material, and may be composed of, for example, materials different from each other. Further, the low acoustic impedance layers E11 are not limited to the case in which they are composed of the same material, and may be composed of, for example, materials different from each other. Moreover, the configuration is not limited to the case in which the number of high acoustic impedance layers E12 is different from the number of low acoustic impedance layers E11, and the numbers may be the same.

### (2) Heat Dissipation

Next, heat dissipation of the high frequency module 1 according to embodiment 5 is described with reference to FIG. 12.

Heat generated by the first functional electrode 32A of the first acoustic wave filter 3A passes through the first substrate 31A and is dissipated to the bonding conductor 5. The heat dissipated to the bonding conductor 5 is dissipated to the through-conductor 6, and is conducted in the through-conductor 6 to be released to the external of the high frequency module 1.

### (3) Effects

With the high frequency module 1 according to embodiment 5, it is possible to provide a short path as a heat dissipation path from the first acoustic wave filter 3A disposed over the first major surface 21 of the first mounting board 2A to the external connection terminal 11 disposed on the second major surface 22 of the first mounting board 2A similarly to the high frequency module 1 of embodiment 1. Thus, effective heat dissipation is enabled.

### Embodiment 6

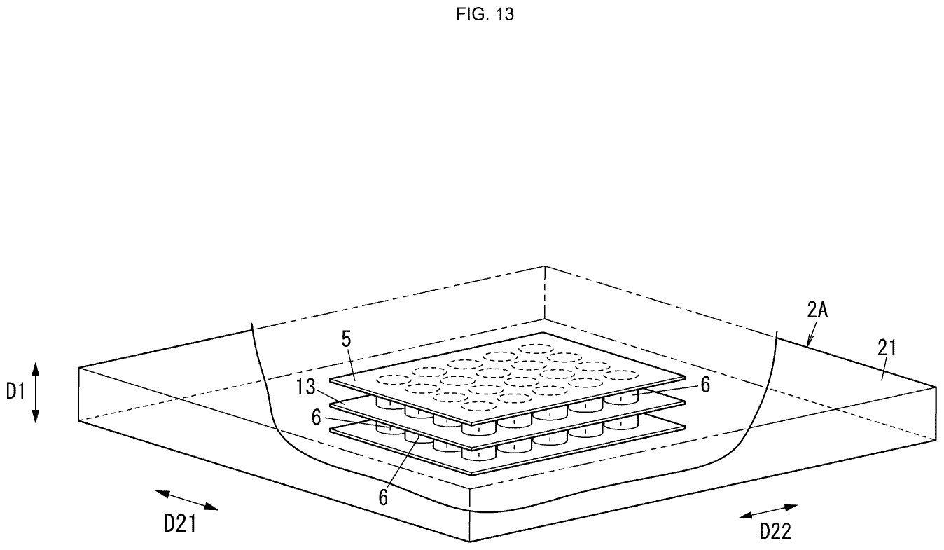

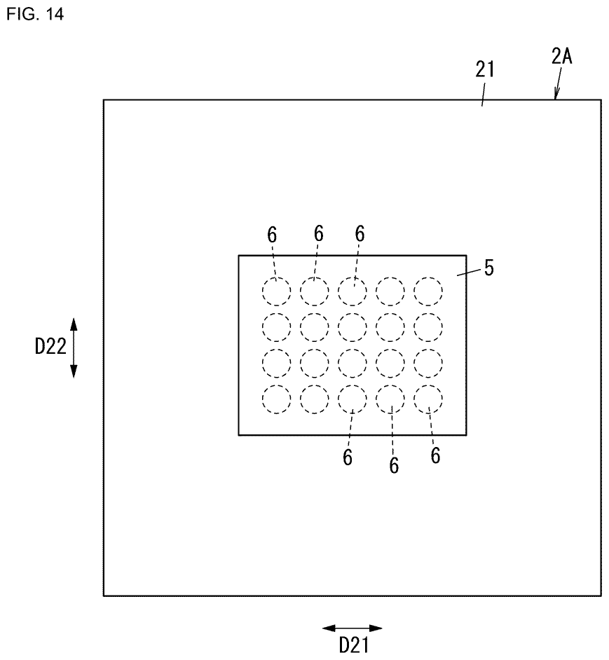

As depicted in FIGS. 13 and 14, the high frequency module 1 according to embodiment 6 is different from the high frequency module 1 according to embodiment 1 (see FIG. 1) in that the high frequency module 1 according to embodiment 6 includes a plurality of through-conductors 6. Concerning the high frequency module 1 according to embodiment 6, a constituent element similar to that of the high frequency module 1 according to embodiment 1 is given the same numeral and description thereof is omitted.

### (1) Configuration

As depicted in FIGS. 13 and 14, the high frequency module 1 according to embodiment 6 includes the first mounting board 2A, the first acoustic wave filter 3 (see FIG. 1), a plurality of external connection terminals 11 (see FIG. 1), the bonding conductor 5, and the plurality of through-conductors 6.

As depicted in FIG. 14, the through-conductors 6 are disposed in a lattice manner in the thickness direction D1 (see FIG. 13) of the first mounting board 2A. Concerning the through-conductor 6 of embodiment 6, description is omitted regarding configurations and functions similar to those of the through-conductor 6 of embodiment 1 (see FIG. 1).

### (2) Heat Dissipation

Next, heat dissipation of the high frequency module 1 according to embodiment 6 is described with reference to FIG. 13.

Heat generated by the first functional electrode 32 of the first acoustic wave filter 3 passes through the first substrate 31 and is dissipated to the bonding conductor 5. The heat dissipated to the bonding conductor 5 is dissipated to the through-conductors 6, and is conducted in the through-conductors 6 to be released to the external of the high frequency module 1.

This can dissipate the heat from the first acoustic wave filter 3 by the short heat dissipation path.

### (3) Effects

With the high frequency module 1 according to embodiment 6, it is possible to provide a short path as a heat dissipation path from the first acoustic wave filter 3 disposed over the first major surface 21 of the first mounting board 2A to the external connection terminal 11 disposed on the second major surface 22 of the first mounting board 2A similarly to the high frequency module 1 of embodiment 1. Thus, effective heat dissipation is enabled.

### (4) Modifications

Modifications of embodiment 6 are described below.

### (4.1) Modification 1

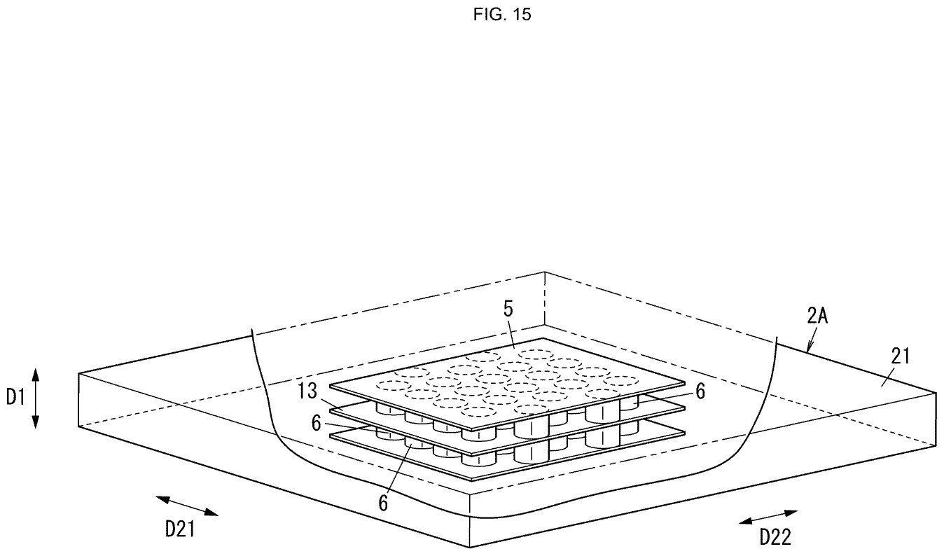

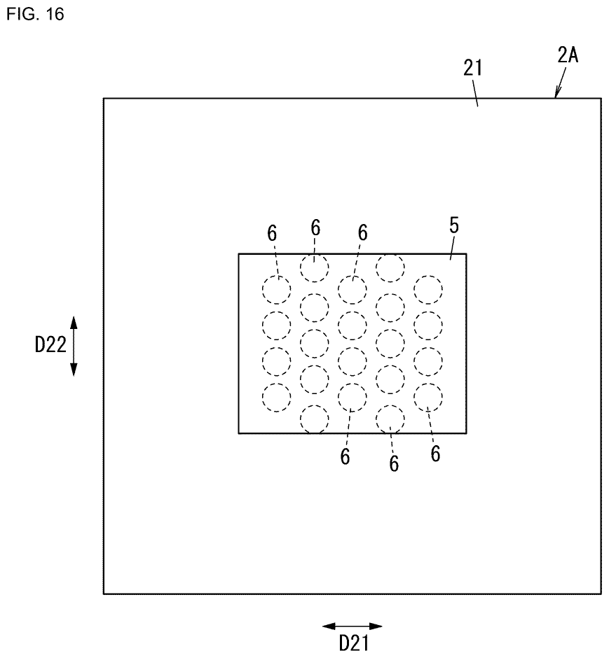

In the high frequency module 1 according to modification 1 of embodiment 6, as depicted in FIGS. 15 and 16, a plurality of through-conductors 6 are disposed in a staggered manner in plan view from the thickness direction of the first mounting board 2A.

### (4.2) Modification 2

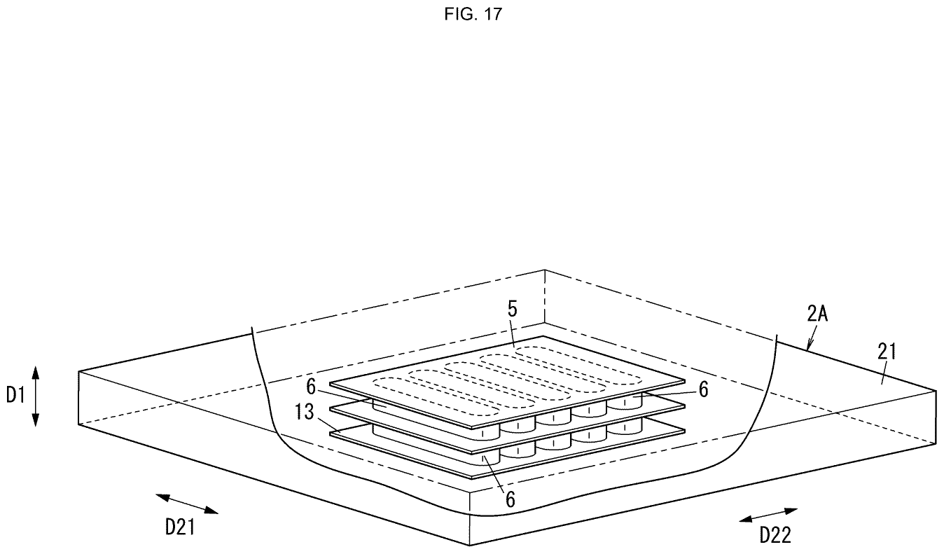

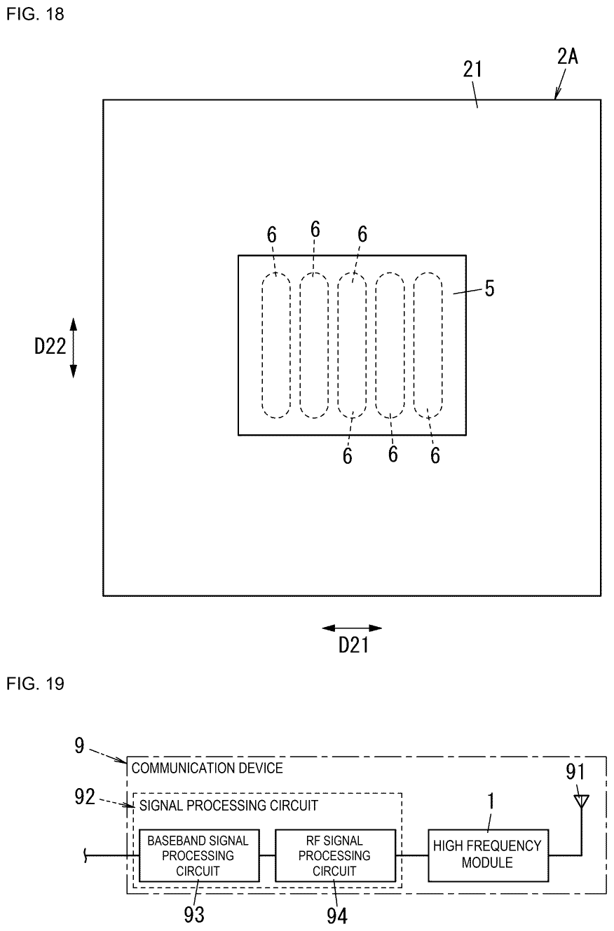

In the high frequency module 1 according to modification 2 of embodiment 6, as depicted in FIGS. 17 and 18, each of a plurality of through-conductors 6 has an elongated shape. Each of the through-conductors 6 is elongated in the first direction D21 in plan view from the thickness direction D1 of the first mounting board 2A. The through-conductors 6 are arranged along the second direction D22.

The high frequency modules 1 according to the above-described respective modifications also provide effects similar to those of the high frequency module 1 according to embodiment 6.

### Embodiment 7

In embodiment 7, a communication device 9 including the high frequency module 1 is described.

### (1) Configuration

As depicted in FIG. 19, the communication device 9 according to embodiment 7 includes the high frequency module 1, an antenna 91, and a signal processing circuit 92. The communication device 9 is, for example, a portable terminal (for example, smartphone). The communication device 9 is not limited to the portable terminal, and may be, for example, a wearable terminal (for example, smart watch).

The high frequency module 1 according to embodiment 7 is a module having a configuration similar to that of the high frequency module 1 according to embodiment 1. Concerning the high frequency module 1 according to embodiment 7, a constituent element similar to that of the high frequency module 1 according to embodiment 1 is given the same numeral and description thereof is omitted.

The high frequency module 1 is configured to amplify a transmission signal (high frequency signal) from the signal processing circuit 92 and output the transmission signal to the antenna 91. Further, the high frequency module 1 is configured to amplify a received signal (high frequency signal) received by the antenna 91 and output the received signal to the signal processing circuit 92. The high frequency module 1 is controlled by, for example, the signal processing circuit 92.

The high frequency module 1 is a module compatible with, for example, the 4th generation mobile communication (4G) standard and the 5th generation mobile communication (5G) standard. The 4G standard is, for example, the Third Generation Partnership Project (3GPP, registered trademark) standard or the Long Term Evolution (LTE, registered trademark) standard. The 5G standard is, for example, 5G New Radio (NR). The high frequency module 1 is a module compatible with carrier aggregation and dual connectivity.

In the communication device 9, the high frequency module 1 can be electrically connected to an external board. The external board corresponds to, for example, a motherboard of a portable terminal, communication equipment, and the like. The expression “the high frequency module 1 can be electrically connected to an external board” includes not only a case in which the high frequency module 1 is directly mounted on the external board but also a case in which the high frequency module 1 is indirectly mounted over the external board. Further, the case in which the high frequency module 1 is indirectly mounted over the external board is a case in which the high frequency module 1 is mounted on another high frequency module mounted on the external board, or the like.

### (1.1) Antenna

The antenna 91 is connected to an antenna terminal of the high frequency module 1. The antenna 91 has a transmitting function of radiating a transmission signal output from the high frequency module 1 by radio waves and a receiving function of receiving a signal as radio waves from the external and outputting the received signal to the high frequency module 1.

### (1.2) Signal Processing Circuit

The signal processing circuit 92 is connected to the high frequency module 1. The signal processing circuit 92 processes a high frequency signal that passes through the high frequency module 1. Specifically, the signal processing circuit 92 is configured to execute signal processing for the received signal received from the high frequency module 1. Moreover, the signal processing circuit 92 is configured to execute signal processing for the transmission signal to be output to the high frequency module 1.

The signal processing circuit 92 includes a baseband signal processing circuit 93 and an RF signal processing circuit 94.

The baseband signal processing circuit 93 is, for example, a baseband integrated circuit (BBIC).

The baseband signal processing circuit 93 executes predetermined signal processing for a signal from the external of the signal processing circuit 92. Specifically, the baseband signal processing circuit 93 generates a transmission signal from a baseband signal (for example, audio signal and image signal) from the external of the signal processing circuit 92, and outputs the generated transmission signal to the RF signal processing circuit 94.

The baseband signal processing circuit 93 executes predetermined signal processing for a signal from the RF signal processing circuit 94. Specifically, the baseband signal processing circuit 93 outputs, to the external, the received signal received from the RF signal processing circuit 94. The received signal processed by the baseband signal processing circuit 93 is, for example, used as an image signal for image display or used as an audio signal for a phone call.

The RF signal processing circuit 94 is, for example, a radio frequency integrated circuit (RFIC), and executes signal processing for high frequency signals (transmission signal and received signal).

The RF signal processing circuit 94 executes the signal processing for the transmission signal output from the baseband signal processing circuit 93, and outputs the transmission signal resulting from the signal processing to the high frequency module 1. Specifically, the RF signal processing circuit 94 executes the signal processing such as up-conversion for the transmission signal output from the baseband signal processing circuit 93, and outputs the transmission signal resulting from the signal processing to a transmission path of the high frequency module 1.

The RF signal processing circuit 94 executes the signal processing for the received signal output from the high frequency module 1, and outputs the received signal resulting from the signal processing to the baseband signal processing circuit 93. Specifically, the RF signal processing circuit 94 executes the signal processing such as down-conversion for the received signal output from a reception path of the high frequency module 1, and outputs the received signal resulting from the signal processing to the baseband signal processing circuit 93.

### (2) Effects

With the communication device 9 according to embodiment 7, it is possible to, in the high frequency module 1, provide a short path as a heat dissipation path from the first acoustic wave filter 3 disposed over the first major surface 21 of the first mounting board 2A to the external connection terminal 11 disposed on the second major surface 22 of the first mounting board 2A. Thus, effective heat dissipation is enabled.

### (3) Modification

A modification of embodiment 7 is described below.

The communication device 9 according to the modification of embodiment 7 may include any of the high frequency modules 1 according to embodiments 2 to 6 instead of the high frequency module 1 according to embodiment 1.

The communication device 9 according to the above-described modification also provides effects similar to those of the communication device 9 according to embodiment 7.

The above-described structure for all embodiments and modifications creates a short, low-resistance path for heat to travel from the filter's electrode, through the filter's substrate, through the bonding conductor and through-conductor, and out via the external terminal to a larger heatsink or ground plane on a motherboard, thereby improving thermal management and device reliability are. The present disclosure is not limited to only the above-described embodiments and modifications, which are merely exemplary. It will be appreciated by those skilled in the art that the disclosed systems and/or methods can be embodied in other specific forms without departing from the spirit of the disclosure or essential characteristics thereof. The presently disclosed embodiments are therefore considered to be illustrative and not restrictive. The disclosure is not exhaustive and should not be interpreted as limiting the claimed invention to the specific disclosed embodiments. In view of the present disclosure, one of skill in the art will understand that modifications and variations are possible in light of the above teachings or may be acquired from practicing of the disclosure. The scope of the invention is indicated by the appended claims, rather than the foregoing description.

What is claimed is:

1. A high frequency module comprising:
a first mounting board having a first major surface and a second major surface opposite to each other;
a first acoustic wave filter disposed over the first major surface of the first mounting board;
an external connection terminal disposed on the second major surface of the first mounting board;
a first bonding conductor disposed between the first major surface of the first mounting board and the first acoustic wave filter; and
a first through-conductor that penetrates the first mounting board in a thickness direction of the first mounting board and is connected to the external connection terminal and the first bonding conductor, wherein
the first acoustic wave filter has
a first substrate that has a third major surface and a fourth major surface opposite to each other and includes a piezoelectric body, and
a first functional electrode disposed on the third major surface of the first substrate,
the fourth major surface of the first substrate is connected to the first bonding conductor, and
the first bonding conductor and the first through-conductor overlap with the first functional electrode of the first acoustic wave filter in plan view from the thickness direction of the first mounting board.

2. The high frequency module according to claim 1, wherein
the first bonding conductor overlaps with whole of the fourth major surface of the first substrate of the first acoustic wave filter in plan view from the thickness direction of the first mounting board.

3. The high frequency module according to claim 1, further comprising:
a first resin member that covers at least part of the first acoustic wave filter disposed over the first major surface of the first mounting board;
a first shield layer that covers a side surface of the first resin member and at least part of the first mounting board; and
a ground layer that is disposed inside the first mounting board and is connected to the first through-conductor, wherein
at least part of the ground layer is exposed in a side surface of the first mounting board and is connected to the first shield layer.

4. The high frequency module according to claim 1, wherein
the first mounting board has
a first dielectric layer,
a second dielectric layer,
a via conductor that penetrates the first dielectric layer, and
a wiring conductor disposed in the second dielectric layer,
the via conductor does not overlap with the first functional electrode of the first acoustic wave filter in the thickness direction of the first mounting board, and
the wiring conductor overlaps with the via conductor in the thickness direction of the first mounting board.

5. The high frequency module according to claim 1, wherein
the first mounting board further has a signal terminal disposed on the first major surface,
the first acoustic wave filter further has a first connection terminal, and
the first connection terminal is connected to the signal terminal through a bonding wire.

6. The high frequency module according to claim 1, further comprising:
a second mounting board having a fifth major surface and a sixth major surface opposite to each other; and
a second acoustic wave filter disposed on the fifth major surface of the second mounting board, wherein
the first acoustic wave filter further has a first connection terminal, and
the first connection terminal is connected to the sixth major surface of the second mounting board.

7. The high frequency module according to claim 6, further comprising:
a second resin member that covers at least part of the second acoustic wave filter; and
a second shield layer that covers at least part of a side surface of the second resin member, wherein
the second acoustic wave filter has
a second substrate having a seventh major surface and an eighth major surface opposite to each other, and
a second functional electrode and a second connection terminal disposed on a side of the seventh major surface of the second substrate, and
the eighth major surface of the second substrate is connected to the second shield layer.

8. The high frequency module according to claim 6, wherein
the first acoustic wave filter allows a transmission signal to pass through the first acoustic wave filter, and
the second acoustic wave filter allows a received signal to pass through the second acoustic wave filter.

9. The high frequency module according to claim 8, wherein the first acoustic wave filter is part of a transmission path of the high frequency module and the second acoustic wave filter is part of a reception path of the high frequency module.

10. The high frequency module according to claim 1, wherein the first through-conductor comprises a plurality of through-conductors.

11. The high frequency module according to claim 10, wherein the plurality of through-conductors are arranged in a lattice pattern, a staggered pattern, or as a plurality of parallel elongated strips.

12. The high frequency module according to claim 1, wherein the external connection terminal is configured to be connected to a ground plane of an external board.

13. The high frequency module according to claim 1, wherein the first bonding conductor and the first through-conductor establish a primary thermally conductive path from the first functional electrode to the external connection terminal.

14. The high frequency module according to claim 1, wherein the first acoustic wave filter includes an acoustic reflection layer between the first substrate and the first functional electrode.

15. The high frequency module according to claim 1, wherein the external connection terminal has a surface area on the second major surface that is larger than a cross-sectional area of the first through-conductor where it connects to the external connection terminal.

16. A communication device comprising:
the high frequency module according to claim 1; and
a signal processing circuit connected to the high frequency module.

17. The communication device according to claim 16, further comprising an antenna connected to the high frequency module, wherein the signal processing circuit is configured to process signals transmitted from or received by the antenna.

18. A method of manufacturing a high frequency module, the method comprising:
providing a first mounting board having a first major surface and a second major surface opposite to each other;
forming a first through-conductor penetrating the first mounting board from the first major surface to the second major surface;
disposing an external connection terminal on the second major surface, the external connection terminal being connected to the first through-conductor;
disposing a first bonding conductor on the first major surface, the first bonding conductor being connected to the first through-conductor; and
mounting a first acoustic wave filter over the first major surface, the first acoustic wave filter having a first substrate and a first functional electrode disposed on a third major surface of the first substrate,
wherein mounting the first acoustic wave filter comprises connecting a fourth major surface of the first substrate to the first bonding conductor such that the first bonding conductor and the first through-conductor overlap with the first functional electrode in a plan view from a thickness direction of the first mounting board.

19. The method according to claim 18, wherein mounting the first acoustic wave filter includes wire bonding a first connection terminal of the first acoustic wave filter to a signal terminal on the first major surface of the first mounting board.
